(19) United States
(12) Patent Application Publication
(10) Pub. No.: US 2026/0293250 A1
(43) Pub. Date: Sep. 24, 2026

(54) RADIATION HARDENED (RAD-HARD) DEVICES INCLUDING A SUPERLATTICE RESERVOIR LAYER AND RELATED METHODS

(71) Applicant: ATOMERA INCORPORATED, LOS GATOS, CA (US)

(72) Inventors: ROBERT J. MEARS, WELLESLY, MA (US); MAREK HYTHA, BROOKLINE, MA (US); KEITH DORAN WEEKS, CHANDLER, AZ (US); NYLES WYNN CODY, TEMPE, AZ (US); ROBERT MICHAEL VYNE, CHANDLER, AZ (US); MARK LI, TEMPE, AZ (US)

(21) Appl. No.: 19/568,062

(22) Filed: Mar. 16, 2026

Related U.S. Application Data
(60) Provisional application No. 63/773,645, filed on Mar. 18, 2025.

(51) Int. Cl. H10D 62/815; H10D 62/00; H10D 62/60

(52) U.S. Cl. CPC H10D 62/8162; H10D 62/01; H10D 62/60

(57) ABSTRACT

A radiation-hardened (rad-hard) semiconductor device may include a semiconductor layer having at least one active device region therein, and a radiation passivation layer including a superlattice adjacent the at least one active device region. The superlattice may include stacked layer groups, with each layer group including stacked base semiconductor monolayers defining a base semiconductor portion, and at least one non-semiconductor monolayer constrained within a crystal lattice of adjacent base semiconductor portions. The radiation passivation layer may further include a passivating species in the superlattice configured to release therefrom to passivate radiation-induced defects in the at least one active device region.

### RELATED APPLICATIONS

This application claims the benefit of U.S. App. no. 63/773,645 filed Mar. 18, 2025, which is hereby incorporated herein in its entirety by reference.

### TECHNICAL FIELD

The present disclosure generally relates to semiconductor devices, and, more particularly, to radiation hardened (rad-hard) devices and related methods.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region includes alternate layers of SiO2/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A radiation-hardened (rad-hard) semiconductor device may include a semiconductor layer having at least one active device region therein, and a radiation passivation layer including a superlattice adjacent the at least one active device region. The superlattice may include a plurality of stacked layer groups, with each layer group comprising a plurality of stacked base semiconductor monolayers defining a base semiconductor portion, and at least one non-semiconductor monolayer constrained within a crystal lattice of adjacent base semiconductor portions. The radiation passivation layer may further include a passivating species in the superlattice configured to release therefrom to passivate radiation-induced defects in the at least one active device region.

By way of example, the passivating species may comprise hydrogen, deuterium, semiconductor interstitials, etc. Also by way of example, the superlattice may have a thickness in a range of about 50 nm to about 400 nm, and the passivating species may be present in the superlattice at a concentration in a range of about 10¹⁷ atoms/cm³ to about 10²¹ atoms/cm³.

In some embodiment, the superlattice may be oriented laterally with respect to the at least one active device region. In other embodiments, the superlattice is positioned on a sidewall of a trench defined in the semiconductor layer. By way of example, each base semiconductor portion may comprise silicon, and the at least one non-semiconductor monolayer may comprise oxygen.

A related radiation-hardened (rad-hard) electronic system may include a semiconductor layer having at least one active device region therein, and a radiation passivation layer including a superlattice, such as the one described briefly above, adjacent the at least one active device region. The radiation passivation layer may further include a passivating species in the superlattice configured to release therefrom to passivate radiation-induced defects in the at least one active device region, and a heater thermally coupled to the radiation passivation layer and configured to selectively heat the superlattice to release the passivating species therefrom.

A related method is also provided for making a rad-hard semiconductor device. The method may include forming a semiconductor layer having at least one active device region therein, and forming a radiation passivation layer adjacent the at least one active device region and comprising a superlattice, such as the one described briefly above. The method may further include incorporating a passivating species in the superlattice configured to release therefrom to passivate radiation-induced defects in the at least one active device region.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIG. 4 is a schematic block diagram of a radiation-hardened (rad-hard) electronic system including a superlattice radiation passivation layer in accordance with an example embodiment.

FIG. 5 is a schematic cross-sectional view of a rad-hard semiconductor device incorporating a silicon-on-insulator (SOI) substrate and a superlattice radiation passivation layer in accordance with an example embodiment.

FIG. 6 is a table illustrating example parameter ranges for a hydrogen passivating species reservoir in a superlattice radiation passivation layer in accordance with an example embodiment.

FIG. 7 is a table illustrating example hydrogen diffusion characteristics at various operating temperatures for a superlattice radiation passivation layer in accordance with an example embodiment.

FIG. 8 is a table illustrating example reservoir lifetime scenarios under varying radiation intensity and operating temperature conditions for a superlattice radiation passivation layer in accordance with an example embodiment.

FIG. 9 is a flowchart illustrating a method for making a rad-hard semiconductor device including a superlattice radiation passivation layer in accordance with an example embodiment.

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to semiconductor devices having an enhanced semiconductor superlattice therein to provide performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. In prior work, Applicant theorized that certain superlattices as described herein reduce the effective mass of charge carriers, and that this accordingly leads to higher charge carrier mobility. See, e.g., U.S. Pat. No. 6,897,472, which is hereby incorporate herein in its entirety by reference.

Further development by Applicant has established that the presence of MST layers may advantageously improve the mobility of free carriers in semiconductor materials, e.g., at interfaces between silicon and insulators like SiO₂ or HfO₂. Applicant theorizes, without wishing to be bound thereto, that this may occur due to various mechanisms. One mechanism is by reducing the concentration of charged impurities proximate to the interface, by reducing the diffusion of these impurities, and/or by trapping the impurities so they do not reach the interface proximity. Charged impurities cause Coulomb scattering, which reduces mobility. Another mechanism is by improving the quality of the interface. For example, oxygen emitted from an MST film may provide oxygen to a Si—SiO₂ interface, reducing the presence of sub-stoichiometric SiOₓ. Alternately, the trapping of interstitials by MST layers may reduce the concentration of interstitial silicon proximate to the Si—SiO₂ interface, reducing the tendency to form sub-stoichiometric SiOₓ. Sub-stoichiometric SiOₓ at the Si—SiO₂ interface is known to exhibit inferior insulating properties relative to stoichiometric SiO₂. Reducing the amount of sub-stoichiometric SiOₓ at the interface more effectively confines free carriers (electrons or holes) in the silicon, and thus improves the mobility of these carriers due to electric fields applied parallel to the interface, as is standard practice in field effect transistor (“FET”) structures. Scattering due to the direct influence of the interface is called “surface-roughness scattering”, which may advantageously be reduced by the proximity of MST layers followed by anneals or during thermal oxidation.

In addition to the enhanced mobility characteristics of MST structures, they may also be formed or used in such a manner that they provide piezoelectric, pyroelectric, and/or ferroelectric properties that are advantageous for use in a variety of different types of devices, as discussed further in U.S. Pat. No. 7,517,702, which is also from the present Applicant and is hereby incorporated herein in its entirety by reference.

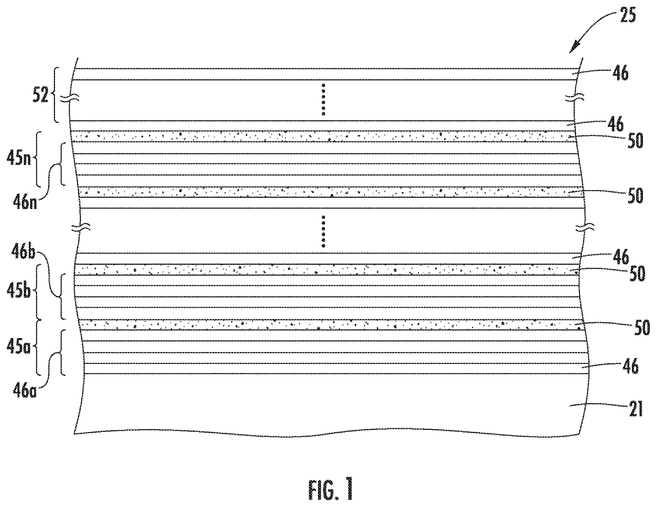

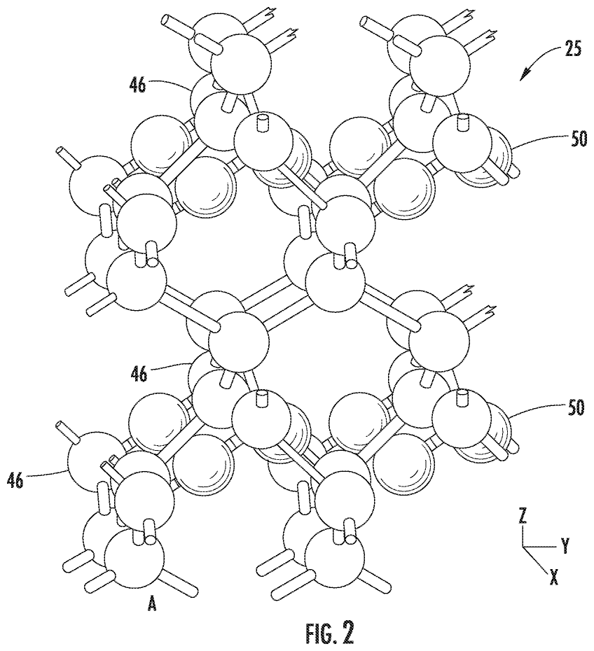

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and a non-semiconductor monolayer(s) 50 thereon. The non-semiconductor monolayers 50 are indicated by stippling in FIG. 1 for clarity of illustration.

The non-semiconductor monolayer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Moreover, this superlattice structure may also advantageously act as a barrier to dopant and/or material diffusion between layers vertically above and below the superlattice 25. These properties may thus advantageously allow the superlattice 25 in one example implementation to provide an interface for high-K dielectrics which not only reduces diffusion of the high-K material into the channel region, but which may also advantageously reduce unwanted scattering effects and improve device mobility, as will be appreciated by those skilled in the art.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably, between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each non-semiconductor monolayer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art.

It should be noted that the term monolayer is meant to include a single atomic layer and also a single molecular layer. It is also noted that the non-semiconductor monolayer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed, it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the invention may be readily adopted and implemented, as will be appreciated by those skilled in the art.

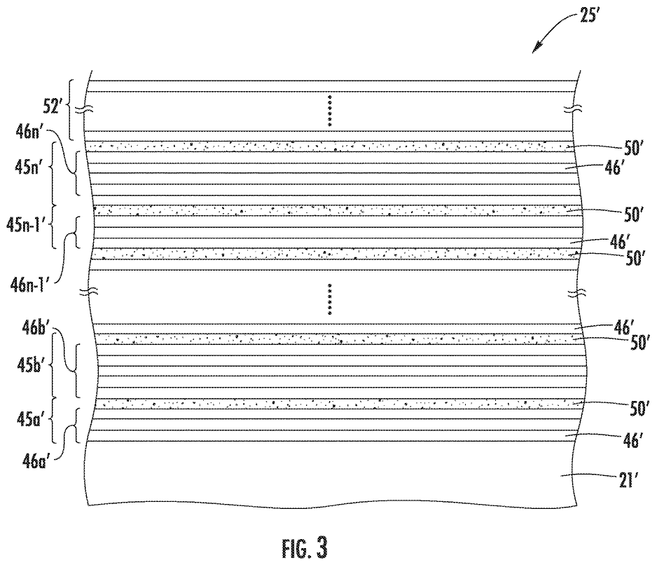

Referring now additionally to FIG. 3, another embodiment of a superlattice 25′ in accordance with the invention having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The non-semiconductor monolayers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

The above-described MST films may be incorporated within various radiation hardened (rad-hard) semiconductor devices to provide significant technical advantages. By way of background, rad-hard devices are specialized electronic components designed to withstand extreme radiation environments where conventional electronics would otherwise fail. These devices may operate in challenging settings including space missions, nuclear facilities, particle accelerators, military applications, and certain medical equipment where radiation exposure occurs. Radiation causes various failures in electronics through single-event effects, total ionizing dose damage, displacement damage, and enhanced low-dose rate sensitivity, for example.

Examples of rad-hard components include specialized microprocessors and microcontrollers, radiation-resistant memory devices, hardened power management integrated circuits, specialized sensors and analog components, radiation-tolerant field-programmable gate arrays, and even radiation-resistant passive components. These components are designed using various techniques including special manufacturing processes, redundant circuits, error correction, and radiation-shielding materials to help ensure reliable operation in radiation-intense environments. The technique described herein may be used in the above-noted rad-hard devices.

Referring now to FIG. 4, one or more MST films (superlattices) may be incorporated in rad-hard electronic devices as a radiation passivation layer to provide a reservoir for passivating species such as hydrogen (H) or deuterium (D), which may be selectively released over the lifespan of the device to passivate radiation-induced damage defects, such as dangling bonds. In the illustrated embodiment, a rad-hard electronic system 100 includes a semiconductor layer 101 comprising a substrate 102 and an epitaxial layer 103 formed thereon, with an active device region 104 defined within the epitaxial layer. A superlattice 125 is formed adjacent the active device region 104—in the illustrated example, between the substrate 102 and the epitaxial layer 103—and serves as a radiation passivation layer containing a passivating species for selective release into the active device region 104. Generally speaking, a relatively thick superlattice 125 (e.g., in a range of about 50 nm to about 400 nm) is formed as a species reservoir for elements such as H, D, and/or Si interstitials. Elements such as H or D may be diffused into the superlattice 125 via a high-pressure, high-concentration environment at relatively low temperatures (e.g., approximately 200° C. for H), and Si interstitials may be introduced into the superlattice 125 through high-temperature oxidation processes performed after formation of the superlattice.

The illustrated system 100 further includes a heater 105 thermally coupled to the semiconductor layer 101, a controller 106 coupled to the heater 105, and a radiation detector 107 coupled to the controller 106. The passivating species stored within the superlattice 125 may be released responsive to radiation events detected by the radiation detector 107, which signals the controller 106 to actuate the heater 105 to selectively heat the superlattice 125, thereby driving release of the passivating species into the active device region 104. However, it will be appreciated that in other embodiment different release mechanisms may be used, including passive release from radiation-induced displacement (e.g., in the case of hydrogen), as well as electrical stimulated annealing.

This provides a “self-healing” structure that actively repairs radiation-induced defects as the device is irradiated. The released H or D atoms diffuse rapidly through the semiconductor material to Si—SiO₂ interfaces and other defect sites, passivating radiation-generated dangling bonds and interface states, thereby reducing threshold voltage shift, suppressing subthreshold leakage, and stabilizing device performance. Other materials, such as boron, may also be incorporated in the superlattice 125 to help reduce defects, for example by providing neutron shielding. It should be noted that a lateral superlattice configuration is shown in FIG. 4, but other film configurations—for example, vertical orientations such as on a trench sidewall—may also be used in some embodiments to position the reservoir layer adjacent sensitive device regions to be repaired.

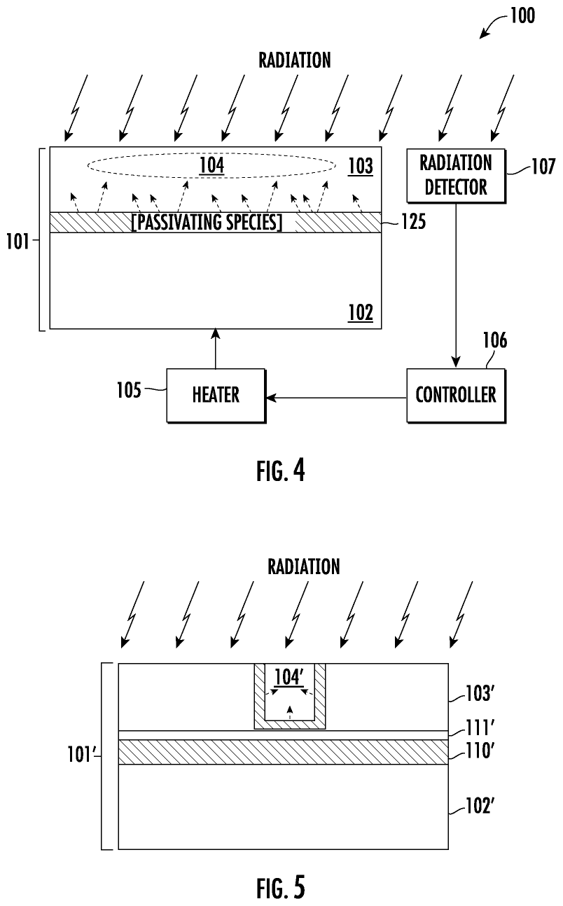

Referring now to FIG. 5, another embodiment of a rad-hard semiconductor device 100′ is illustrated in which the semiconductor layer 101′ comprises a silicon-on-insulator (SOI) substrate configuration. More particularly, the semiconductor layer 101′ includes a substrate 102′, a buried oxide (BOX) layer 110′ formed on the substrate 102′, and a semiconductor seed layer 111′ formed on the BOX layer 110′, with an epitaxial layer 103′ grown on the semiconductor seed layer 111′. An active device region 104′ is defined within the epitaxial layer 103′. In this SOI embodiment, the semiconductor seed layer 111′ may comprise or incorporate the superlattice radiation passivation layer (i.e., the MST film functioning as a species reservoir), positioned beneath the epitaxial layer 103′ and on trench sidewalls adjacent the active device region 104′, to provide a localized reservoir of passivating species in close proximity to the sensitive device regions that may be subject to radiation-induced damage. The superlattice reservoir layer may be formed as part of the SOI substrate structure, advantageously enabling integration with standard SOI fabrication processes while providing the self-healing reservoir capability described herein.

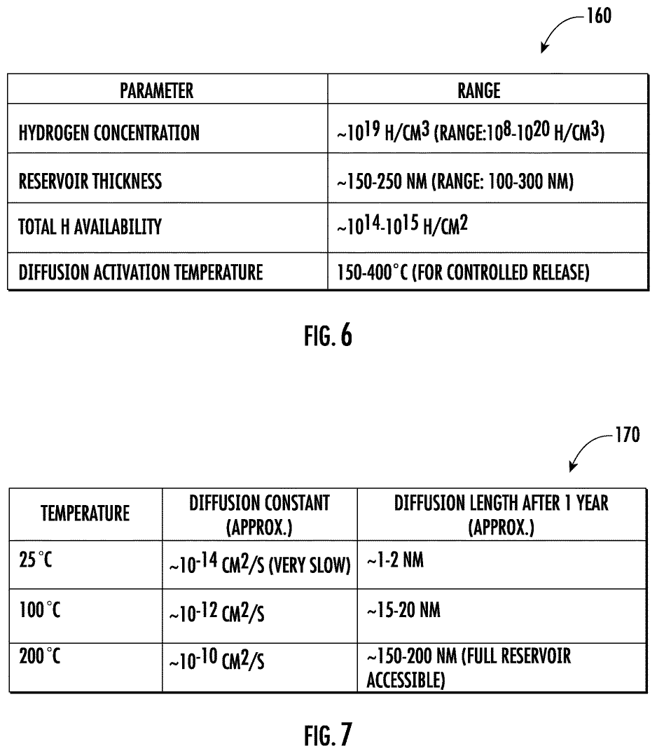

Referring now to FIG. 6, a table 160 illustrates example parameter ranges for hydrogen as an example passivating species stored in the superlattice radiation passivation layer 125. In an example implementation, the hydrogen concentration in the superlattice reservoir is approximately 10¹⁹ H/cm³, with a suitable range of about 10¹⁸ to about 10²⁰ H/cm³. An example reservoir thickness is in the range of about 150 nm to about 250 nm, with an overall preferred range of about 100 nm to about 300 nm (and up to about 400 nm in some embodiments), which provides a total hydrogen availability of approximately 10¹⁴ to 10¹⁵ H/cm². The diffusion activation temperature for controlled release of hydrogen from the superlattice reservoir is in the range of about 150° C. to about 400° C., which is achievable by the heater 105 (FIG. 4) under actuation of the controller 106. It will be appreciated that similar concentration and thickness parameter ranges may be applied to other passivating species, such as deuterium and Si interstitials.

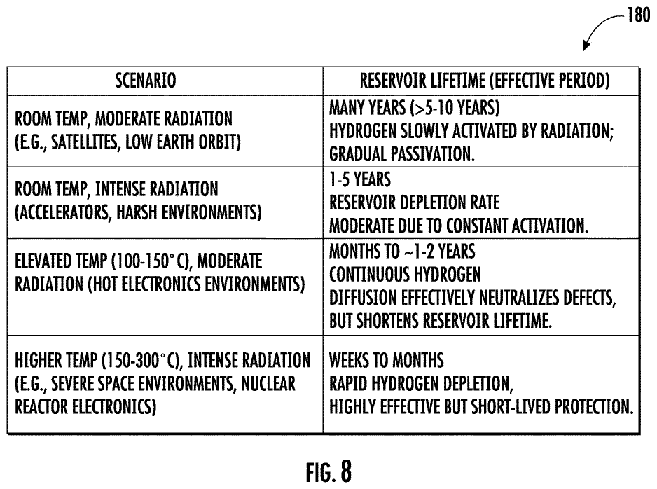

Referring now to FIG. 7, a table 170 illustrates example hydrogen diffusion characteristics at various operating temperatures for the superlattice reservoir layer 125. At room temperature (approximately 25° C.), the hydrogen diffusion constant is approximately 10⁻¹⁴ cm²/s, yielding a diffusion length of approximately 1-2 nm per year—effectively negligible—such that the reservoir remains substantially intact during storage or ambient-temperature operation. At approximately 100° C., the diffusion constant increases to approximately 10⁻¹² cm²/s, providing a diffusion length of approximately 15-20 nm per year, allowing for some passive hydrogen delivery to nearby defect sites during operation in warm electronic environments. At approximately 200° C.—a temperature readily achievable by actuating the heater 105—the diffusion constant increases to approximately 10⁻¹⁰ cm²/s, providing a diffusion length of approximately 150-200 nm per year, making substantially the full reservoir thickness accessible for delivering hydrogen to passivate radiation-induced defects throughout the active device region 104. These diffusion characteristics confirm that the combination of the superlattice reservoir and the controllable heater 105 enables on-demand, thermally activated release of the passivating species.

Referring now to FIG. 8, a table 180 illustrates example reservoir lifetime scenarios under various combinations of radiation intensity and operating temperature. At room temperature with moderate radiation exposure (e.g., low Earth orbit satellites), the reservoir lifetime is estimated to exceed five to ten years or more, as hydrogen is gradually released and passivates defects at a slow depletion rate. At room temperature with intense radiation (e.g., harsh space environments or particle accelerators), the estimated reservoir lifetime is approximately one to five years, as more frequent radiation events activate hydrogen at a moderate depletion rate. At elevated operating temperatures of approximately 100° C. to 150° C. with moderate radiation (e.g., thermally stressed electronics environments), the estimated lifetime is approximately months to two years, as continuously elevated diffusion provides effective but faster-depleting passivation. Under high-temperature (approximately 150° C. to 300° C.) and intense radiation conditions, the reservoir undergoes rapid hydrogen depletion on the order of weeks to months, providing highly effective but shorter-lived protection suitable for the most demanding radiation environments.

It is noted that each passivation event consumes one atom of the passivating species—for example, one H atom is consumed per dangling bond passivated—such that the reservoir is gradually depleted over the operational lifetime of the device as radiation-induced defects are generated and repaired. Accordingly, the overall reservoir lifetime is governed by both the total available supply of the passivating species and the cumulative rate of defect generation, and these factors should be considered together when designing the reservoir for a target application. Strategies to help maximize reservoir longevity and effectiveness may include selecting a greater reservoir thickness to increase the total available supply of passivating species; using deuterium in place of hydrogen, given deuterium's lower diffusivity and consequently slower rate of passive depletion at a given temperature; minimizing passive reservoir loss by maintaining device operating temperatures as low as practicable during periods of low or no radiation exposure; and tailoring the heater 105 actuation profile so that the controller 106 releases the passivating species only as needed in direct response to detected radiation events, rather than allowing continuous passive diffusion. The data in tables 160 (FIGS. 6) and 170 (FIG. 7) may be used in conjunction with the lifetime scenarios of table 180 to optimize reservoir design parameters for a given mission profile or operational environment.

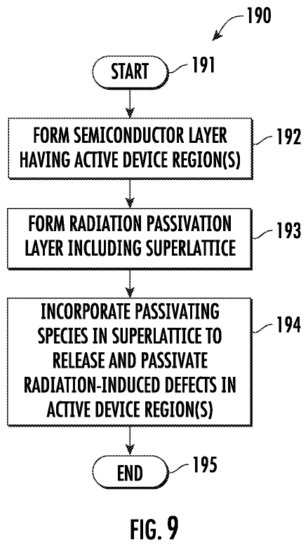

Referring now to FIG. 9, a flowchart 190 illustrates a method for making a rad-hard semiconductor device in accordance with an example embodiment, beginning at block 191. At block 192, a semiconductor layer (e.g., semiconductor layer 101) is formed having at least one active device region (e.g., active device region 104) therein. At block 193, a radiation passivation layer comprising a superlattice (e.g., superlattice 125) is formed adjacent the at least one active device region, as described above with reference to FIGS. 1-3. At block 194, a passivating species—for example, hydrogen, deuterium, or Si interstitials—is incorporated in the superlattice and configured to release therefrom to passivate radiation-induced defects in the at least one active device region. The method concludes at block 195.

In some embodiments, the method may further include coupling a heater (e.g., heater 105) thermally to the semiconductor layer and coupling a controller (e.g., controller 106) to the heater such that the controller may actuate the heater responsive to a radiation event detected by a radiation detector (e.g., radiation detector 107) to selectively heat the superlattice and release the passivating species to repair radiation-induced defects. The method may further include forming the semiconductor layer as an SOI substrate (FIG. 5), and incorporating the superlattice as or within a semiconductor seed layer (e.g., seed layer 111′) formed between the epitaxial layer (e.g., layer 103′) and the BOX layer (e.g., BOX layer 110′).

The superlattice reservoir layer approach described herein provides significant technical advantages in addressing the principal categories of radiation-induced damage in semiconductor devices. With respect to total ionizing dose (TID) damage, ionizing radiation creates electron-hole pairs that become trapped as interface states and charge traps at Si—SiO₂ interfaces and within bulk silicon, severely degrading transistor reliability. The released H or D atoms from the superlattice reservoir diffuse rapidly to these Si—SiO₂ interfaces and into the bulk silicon regions, passivating the radiation-generated interface states and neutralizing electrically active trap sites. The result is a measurable reduction in threshold voltage shift, reduced subthreshold leakage current, and stable device performance over prolonged exposure to ionizing radiation. With respect to displacement damage, energetic particles such as neutrons, protons, and heavy ions physically displace silicon atoms from their lattice sites, creating vacancies, interstitials, and complex defect clusters that increase recombination rates and degrade minority carrier properties. H or D atoms released from the superlattice reservoir and migrating through the silicon crystal are able to occupy interstitial sites, passivate vacancies, and reduce the electrical activity of silicon interstitial defects, thereby reducing recombination rates. The result is mitigated degradation of minority carrier lifetime and mobility, preserving critical device parameters even after severe radiation exposure. More generally, the release of passivating species from the superlattice reservoir reduces trap density and the number of recombination centers, yielding improved post-radiation electronic stability across both TID and displacement damage failure modes.

A further and particularly significant technical advantage of the described approach is the intrinsic self-healing capability it confers upon the device in some embodiments. Because defect generation itself can trigger release of H or D atoms from the superlattice reservoir—thermally, electrically, or by the radiation event itself—the passivating species are delivered to newly formed defect sites rapidly and automatically, without requiring external intervention. This allows the device to recover after transient radiation events and to maintain functional performance in sustained radiation environments, providing a degree of intrinsic robustness not achievable by conventional passive hardening techniques alone. The cumulative reliability benefits of this approach include stable device performance over extended periods in radiation-rich environments; reduction in radiation-induced drift of critical electrical parameters, including threshold voltage stability, transconductance preservation, and reduced leakage currents; and improved long-term device qualification for harsh environments such as space missions, particle accelerators, and nuclear installations. These advantages, taken together, establish the superlattice reservoir layer as an enhanced approach to radiation hardening that addresses multiple radiation damage mechanisms through a single, integrated, process-compatible structural element.

Additional details regarding the use of MST superlattices in rad-hard devices are set forth in the co-pending application assigned attorney docket no. 6260133, also from the present Applicant, which is hereby incorporated herein in its entirety by reference.

Many modifications and other embodiments of the invention will come to the mind of one skilled in the art having the benefit of the teachings presented in the foregoing descriptions and the associated drawings. Therefore, it is understood that this disclosure is not to be limited to the specific embodiments disclosed, and that other modifications and embodiments are intended to be included within the scope of this disclosure.

1. A radiation-hardened (rad-hard) semiconductor device comprising:
a semiconductor layer having at least one active device region therein; and
a radiation passivation layer comprising
a superlattice adjacent the at least one active device region, the superlattice comprising a plurality of stacked layer groups, each layer group comprising a plurality of stacked base semiconductor monolayers defining a base semiconductor portion, and at least one non-semiconductor monolayer constrained within a crystal lattice of adjacent base semiconductor portions, and
a passivating species in the superlattice configured to release therefrom to passivate radiation-induced defects in the at least one active device region.

2. The rad-hard semiconductor device of claim 1, wherein the passivating species comprises at least one of hydrogen and deuterium.

3. The rad-hard semiconductor device of claim 1, wherein the passivating species comprises semiconductor interstitials.

4. The rad-hard semiconductor device of claim 1, wherein the superlattice has a thickness in a range of about 50 nm to about 400 nm.

5. The rad-hard semiconductor device of claim 1, wherein the passivating species is present in the superlattice at a concentration in a range of about 10¹⁷ atoms/cm³ to about 10²¹ atoms/cm³.

6. The rad-hard semiconductor device of claim 1, wherein the superlattice is oriented laterally with respect to the at least one active device region.

7. The rad-hard semiconductor device of claim 1, wherein the superlattice is positioned on a sidewall of a trench defined in the semiconductor layer.

8. The rad-hard semiconductor device of claim 1, wherein each base semiconductor portion comprises silicon, and the at least one non-semiconductor monolayer comprises oxygen.

9. A radiation-hardened (rad-hard) electronic system comprising:
a semiconductor layer having at least one active device region therein;
a radiation passivation layer comprising
a superlattice adjacent the at least one active device region, the superlattice comprising a plurality of stacked layer groups, each layer group comprising a plurality of stacked base semiconductor monolayers defining a base semiconductor portion, and at least one non-semiconductor monolayer constrained within a crystal lattice of adjacent base semiconductor portions, and
a passivating species in the superlattice configured to release therefrom to passivate radiation-induced defects in the at least one active device region; and
a heater thermally coupled to the radiation passivation layer and configured to selectively heat the superlattice to release the passivating species therefrom.

10. The rad-hard electronic system of claim 9, wherein the passivating species comprises at least one of hydrogen and deuterium.

11. The rad-hard electronic system of claim 9, wherein the passivating species comprises semiconductor interstitials.

12. The rad-hard electronic system of claim 9, wherein the superlattice has a thickness in a range of about 50 nm to about 400 nm.

13. The rad-hard electronic system of claim 9, wherein the passivating species is present in the superlattice at a concentration in a range of about 10¹⁷ atoms/cm³ to about 10²¹ atoms/cm³.

14. The rad-hard electronic system of claim 9, further comprising a controller coupled to the heater and configured to actuate the heater responsive to a detected radiation event.

15. The rad-hard electronic system of claim 9, wherein the semiconductor layer comprises a silicon-on-insulator (SOI) substrate.

16. The rad-hard electronic system of claim 9, wherein the superlattice is oriented laterally with respect to the at least one active device region.

17. The rad-hard electronic system of claim 9, wherein the superlattice is positioned on a sidewall of a trench defined in the semiconductor layer.

18. The rad-hard electronic system of claim 9, wherein each base semiconductor portion comprises silicon.

19. The rad-hard electronic system of claim 9, wherein the at least one non-semiconductor monolayer comprises oxygen.

20. A method for making a radiation-hardened (rad-hard) semiconductor device comprising:
forming a semiconductor layer having at least one active device region therein, and forming a radiation passivation layer adjacent the at least one active device region and comprising a superlattice, the superlattice comprising a plurality of stacked layer groups, each layer group comprising a plurality of stacked base semiconductor monolayers defining a base semiconductor portion, and at least one non-semiconductor monolayer constrained within a crystal lattice of adjacent base semiconductor portions; and
incorporating a passivating species in the superlattice configured to release therefrom to passivate radiation-induced defects in the at least one active device region.

21. The method of claim 20, wherein the passivating species comprises at least one of hydrogen and deuterium.

22. The method of claim 20, wherein the passivating species comprises semiconductor interstitials.

23. The method of claim 20, wherein the superlattice has a thickness in a range of about 50 nm to about 400 nm.

24. The method of claim 20, wherein the passivating species is present in the superlattice at a concentration in a range of about 10¹⁷ atoms/cm³ to about 10²¹ atoms/cm³.

25. The method of claim 20, wherein the superlattice is oriented laterally with respect to the at least one active device region.

26. The method of claim 20, wherein the superlattice is positioned on a sidewall of a trench defined in the semiconductor layer.

27. The method of claim 20, wherein each base semiconductor portion comprises silicon, and the at least one non-semiconductor monolayer comprises oxygen.
